(19) United States
(12) Patent Application Publication
(10) Pub. No.: US 2025/0191648 A1
(43) Pub. Date: Jun. 12, 2025

(54) MEMORY DEVICE AND METHOD OF OPERATING THE SAME

(71) Applicant: Samsung Electronics Co., Ltd., Suwon-si (KR)

(72) Inventors: HOON SHIN, Suwon-si (KR); MINCHUR SHIN, Suwon-si (KR); KI-HEUNG KIM, Suwon-si (KR); WIJONG KIM, Suwon-si (KR); Hoseok SEOL, Suwon-si (KR)

(21) Appl. No.: 18/977,200

(22) Filed: Dec. 11, 2024

(30) Foreign Application Priority Data
Dec. 12, 2023 (KR) 10-2023-0179852
Aug. 16, 2024 (KR) 10-2024-0110005

(51) Int. Cl. G11C 11/4096; G11C 5/06; G11C 11/408

(52) U.S. Cl. CPC G11C 11/4096; G11C 5/063; G11C 11/4087

(57) ABSTRACT

A memory device includes a bank comprising a plurality of memory cells connected to a plurality of wordlines and a plurality of column selection lines, a row hammer management circuit performing a read-modify-write (RMW) operation on count memory cells to read count data corresponding to an activated wordline among the plurality of wordlines, wherein the plurality of memory cells include the count memory cells configured to store the count data representing a number of access to the activated wordline, updating the read count data, and writing the updated count data in the count memory cells, and a control logic selecting a first count column selection line connected to the count memory cells from among the plurality of column selection lines based on writing characteristics of each of the plurality of column selection lines.

### CROSS-REFERENCE TO RELATED APPLICATION(S)

This U.S. non-provisional application claims priority under 35 USC § 119 to Korean Patent Application Nos. 10-2023-0179852, filed on Dec. 12, 2023 and 10-2024-0110005, field on Aug. 16, 2024, in the Korean Intellectual Property Office, the disclosures of each of which are herein incorporated by reference in their entirety.

### BACKGROUND

Example embodiments relate to a memory device and a method of operating the same.

Memory devices are used to store data and may be classified into volatile memory devices and non-volatile memory devices. Volatile memory devices lose their stored data when their power supplies are interrupted. As an example of a volatile memory device, a dynamic random access memory (DRAM) may be used in various devices such as a mobile system, a server, and a graphic device.

An aggressive access to a specific wordline may cause row hammer in which the data stored in memory cells connected to wordlines adjacent to the wordline being repeatedly accessed is lost. Accordingly, there is a need for a memory device that may prevent such row hammer.

### SUMMARY

Example embodiments provide a memory device capable of reliably performing an operation to prevent occurrence of row hammer without increasing an additional area.

According to an embodiment of the present disclosure, a memory device includes a bank comprising a plurality of memory cells connected to a plurality of wordlines and a plurality of column selection lines, a row hammer management circuit performing a read-modify-write (RMW) operation on count memory cells to read count data corresponding to an activated wordline among the plurality of wordlines, wherein the plurality of memory cells include the count memory cells configured to store the count data representing a number of access to the activated wordline, updating the read count data, and writing the updated count data in the count memory cells, and a control logic selecting a first count column selection line connected to the count memory cells from among the plurality of column selection lines based on writing characteristics of each of the plurality of column selection lines.

According to an aspect of the present disclosure, a method of operating a memory device includes selecting a first column selection line from among a plurality of column selection lines as a first count column selection line connected to count memory cells storing count data representing a number of access to each of a plurality of wordlines, based on writing characteristics of each of the plurality of column selection lines, and mapping address information of the first count column selection line to address information of a second column selection line among the plurality of column selection lines.

According to an aspect of the present disclosure, a memory system includes a memory device configured to store data, and a memory controller configured to control the memory device. The memory device includes a bank comprising a plurality of memory cells connected to a plurality of wordlines and a plurality of column selection lines, a row hammer management circuit performing a read-modify-write (RMW) operation on count memory cells to read count data corresponding to an activated wordline among the plurality of wordlines, wherein the plurality of memory cells include the count memory cells configured to store the count data representing a number of access to the activated wordline, updating the read count data, and writing the updated count data in the bank, and a control logic selecting at least one count column selection line connected to the count memory cells from among the plurality of column selection lines based on writing characteristics of each of the plurality of column selection lines.

### BRIEF DESCRIPTION OF DRAWINGS

FIG. 1 is a block diagram of a memory system according to an example embodiment.

FIG. 2 is a diagram illustrating execution time of an RMW operation according to an example embodiment.

FIG. 3 is a flowchart illustrating an example of a count column selection line setting mode of the memory device of FIG. 1.

FIG. 4 is a block diagram illustrating an example of the configuration of a memory controller according to an example embodiment.

FIG. 5 is a block diagram illustrating an example of a memory device according to an example embodiment.

FIG. 6 is a diagram illustrating an example of a bank array according to an example embodiment.

FIG. 7 is a diagram illustrating an example of an address storage circuit of FIG. 5.

FIG. 8 is a diagram illustrating an example of a memory device according to an example embodiment.

FIG. 9 is a diagram illustrating an example of a bank according to an example embodiment.

FIGS. 10A and 10B are diagrams illustrating more detailed examples of blocks included in the bank of FIG. 9.

FIG. 11 is a diagram illustrating an example of an operation to set a count column selection line according to an example embodiment.

FIG. 12 is a diagram illustrating an example of an operation to set a count column selection line according to an example embodiment.

FIG. 13 is a diagram illustrating an example of an operation to set a count column selection line according to an example embodiment.

FIG. 14 is a diagram illustrating an example of an operation to set a count column selection line according to an example embodiment.

FIG. 15 is a flowchart illustrating an operation to set a count column selection line according to an example embodiment.

FIG. 16 is a diagram illustrating an example of a bank according to an example embodiment.

FIG. 17A is a diagram illustrating a more detailed example of a global spare block among blocks of FIG. 16.

FIG. 17B is a diagram illustrating a more detailed example of a normal block among the blocks of FIG. 16.

FIG. 18 is a diagram illustrating an example of an operation to set a count column selection line according to an example embodiment.

FIG. 19 is a diagram illustrating an example of an operation to set a count column selection line according to an example embodiment.

FIG. 20 is a flowchart illustrating an operation to set a count column selection line in a bank including a global spare block according to an example embodiment.

FIG. 21 is a diagram illustrating an example of an operation to set a count column selection line according to an example embodiment.

### DETAILED DESCRIPTION

Hereinafter, example embodiments will be described with reference to the accompanying drawings.

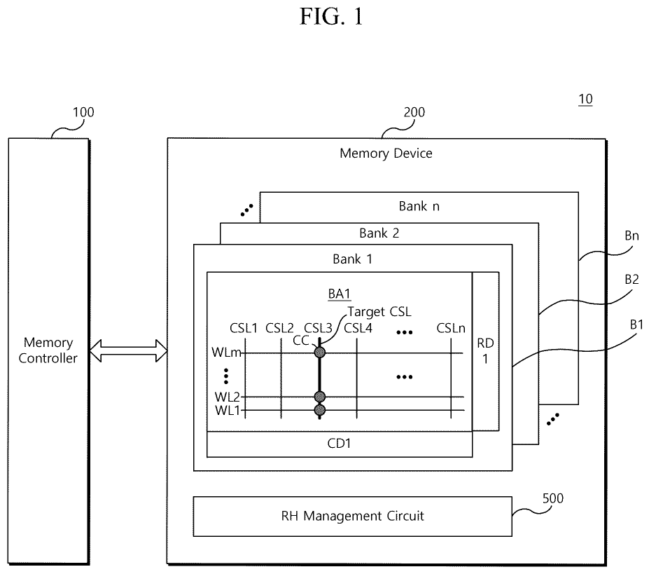

FIG. 1 is a block diagram of a memory system 10 according to an example embodiment.

The memory device 200 according to an example embodiment may include a plurality of banks B1 to Bn. To prevent row hammer caused by an intensive access to a specific wordline, at least one of the plurality of banks B1 to Bn may support a read-modify-write (hereinafter referred to as “RMW”) operation to manage the number of accesses to each of the plurality of wordlines. For example, the memory device 200 may perform an RMW operation to read count data corresponding to a target wordline in an active state, update the read count data, and rewrite the updated count data.

The memory device 200 according to an example embodiment may select at least one column selection line, among a plurality of column selection lines, and store the count data in memory cells connected to the selected count column selection line. For example, the memory device 200 may select a column selection line with relatively good writing characteristics and/or reading characteristics from among the plurality of column selection lines and perform an RMW operation using the selected column selection line, rather than performing an RMW operation using a predetermined column selection line. Accordingly, the memory device 200 according to an example embodiment may reliably perform an operation to prevent row hammer. In addition, an additional space for arranging the column selection line is not required, so that the memory device 200 according to an example embodiment may significantly reduce an increase in area.

Referring to FIG. 1, the memory system 10 may include a memory controller 100 and a memory device 200.

The memory controller 100 may control the memory device 200. For example, the memory controller 100 may control the memory device 200 in response to requests from a processor supporting various applications such as a server application, a PC application, and a mobile application. For example, the memory controller 100 may include a processor and control the memory device 200 in response to requests from the processor.

The memory controller 100 may transmit commands and/or addresses to the memory device 200 to control the memory device. In addition, the memory controller 100 may transmit data to the memory device 200 or receive data from the memory device 200.

The memory device 200 may receive data from the memory controller 100 and store the received data. The memory device 200 may read the stored data in response to a request from the memory controller 100 and transmit the read data to the memory controller 100.

In an example embodiment, the memory device 200 may be a memory device including volatile memory cells. For example, the memory device 200 may be one of various DRAM devices such as a double data rate synchronous dynamic random access memory (DDR SDRAM) device, a DDR2 SDRAM device, a DDR3 SDRAM device, a DDR4 SDRAM device, a DDR5 SDRAM device, a DDR6 SDRAM device, a low power double data rate (LPDDR) SDRAM device, an LPDDR2 SDRAM device, an LPDDR3 SDRAM device, an LPDDR4 SDRAM device, an LPDDR4X SDRAM device, an LPDDR5 SDRAM device, a graphics double data rate synchronous graphics random access memory (GDDR SGRAM) device, a GDDR2 SGRAM device, a GDDR3 SGRAM device, a GDDR4 SGRAM device, a GDDR5 SGRAM device, and a GDDR6 SGRAM device.

In an example embodiment, the memory device 200 may be a stacked memory device in which DRAM dies are stacked, such as a high bandwidth memory (HBM) device, an HBM2 device, an HBM3 device, and an HBM4 device.

In an example embodiment, the memory device 200 may be a memory module such as a dual in-line memory module (DIMM). For example, the memory module 100A may be a registered DIMM (RDIMM), a load reduced DIMM (LRDIMMO, an unbuffered DIMM (UDIMM), a fully buffered DIMM (FB-DIMM), or a small outline DIMM (SO-DIMM). However, this is only an example, and the memory device 200 may be another memory module such as a single in-line memory module (SIMM).

In an example embodiment, the memory device 200 may be a static random access memory (SRAM) device, a NAND flash memory device, a NOR flash memory device, a resistive random access memory (RRAM) device, a Ferroelectric random access memory (FRAM) device, a Phase-change random access memory (PRAM) device, a Thyristor random access memory (TRAM) device, or a Magnetoresistive random access memory (MRAM) device.

The memory device 200 may include a plurality of banks B1 to Bn and a row hammer management circuit 500.

Each of the plurality of banks B1 to Bn may include a bank array, a row decoder, and a column decoder. For example, the first bank B1 may include a first bank array BA1, a first row decoder RD1, and a first column decoder CD1.

Each of the plurality of bank arrays may include memory cells for storing data. For ease of description, an example will be provided in which each bank array includes DRAM cells. However, this is only an example, and each bank array may be implemented to include volatile memory cells other than DRAM cells. Alternatively, each bank array may be implemented to include the same type of memory cells, or may be implemented to include different types of memory cells.

The row decoder may activate a selected wordline among a plurality of wordlines based on a row address. For example, the first row decoder RD1 may activate a selected wordline, among a plurality of wordlines WL1 to WLm of the first bank array BA1, based on a row address.

The column decoder may activate a selected column selection line among a plurality of column selection lines based on a column address. For example, the first column decoder CD1 may activate a selected column selection line, among a plurality of column selection lines CSL1 to CSLm of the first bank array BA1, based on a column address.

In an example embodiment, the memory device 200 may support a count column selection line setting mode for setting a count column selection line among a plurality of column selection lines CSL1 to CSLn. In the count column selection line setting mode, the memory device 200 may select at least one column selection line among the plurality of column selection lines CSL1 to CSLn and set the selected column selection line as a count column selection line.

In an example embodiment, at least one column selection line may be extracted (i.e., selected) from the plurality of column selection lines CSL1 to CSLn through a test operation. For example, a column selection line having relatively good writing characteristics and/or reading characteristics may be extracted from the plurality of column selection lines CSL1 to CSLn. According to example embodiments, a column selection line having relatively good writing characteristics and/or reading characteristics, extracted from the plurality of column selection lines CSL1 to CSLn, may be referred to as a good column selection line. For example, a column selection line having good writing characteristics may refer to a column selection line in which relatively fewer error bits occur during a test operation for a write operation. For example, a column selection line having good writing characteristics may refer to a column selection line in which the number of error bits generated during a test operation for a write operation is below a specific threshold. For example, a column selection line having good reading characteristics may refer to a column selection line in which relatively fewer error bits occur during a test operation for a reading operation. Alternatively, a column selection line having good reading characteristics may refer to a column selection line in which the number of error bits generated during a test operation for a reading operation is below a specific threshold. According to example embodiments, at least one column selection line may be extracted from the plurality of column selection lines CSL1 to CSLn based on characteristics other than the writing characteristics or the reading characteristics. Hereinafter, for ease of description, at least one column selection line extracted from the plurality of column selection lines CSL1 to CSLn will be referred to as a target selection line.

For example, a write and/or read test operation may be performed on a plurality of column selection lines for a relatively small amount of time, compared to a general write and/or read test operation, to extract a target column selection line. Among the plurality of column selection lines, a column selection line having a relatively low error rate may be selected as a target column selection line. For example, a column selection line in which relatively fewer error bits occur during a write and/or read test operation may be selected as a target column selection line. Alternatively, a column selection line in which the number of error bits generated during a write and/or read test operation is below a specific threshold may be selected as a target column selection line. As illustrated in FIG. 1, an example is provided in which among the plurality of column selection lines CSL1 to CSLn of the first bank array BA1, the third column selection line CSL3 has a lowest error rate. The third column selection line CSL3 may be selected as the target column selection line.

In an example embodiment, a portion or all of at least one target column selection line may be set as a count column selection line for storing count data. The count column selection line may refer to a column selection line connected to count cells CC (i.e., count memory cells), and the count cells CC may refer to memory cells storing count data that is an active count of a corresponding wordline. According to an example embodiment, the count column selection line may be referred to as a per row activation count (PRAC) column selection line or a perfect row hammer (PRH) column selection line. For example, among the plurality of column selection lines CSL1 to CSLn of the first bank array BA1, the third column selection line CSL3 having the lowest error rate may be set as the count column selection line, as illustrated in FIG. 1.

The row hammer management circuit 500 may manage the number of accesses to each of the plurality of wordlines WL1 to WLm based on a command received from the memory controller 100.

In an example embodiment, the row hammer management circuit 500 may manage the number of accesses to each of the plurality of wordlines WL1 to WLm using the target column selection line as a count column selection line. For example, the row hammer management circuit 500 may manage the number of accesses to each of the plurality of wordlines WL1 to WLm by storing count data in the count cells CC connected to the target column selection line.

For example, when an active command for a target wordline is received from the memory controller 100, the row hammer management circuit 500 may perform an RMW operation to read count data from the count cell CC of the target wordline connected to the third column selection line CSL3 that is the target column selection line, add ‘1’ to the read count data to generate updated count data, and rewrite the updated count data in the count cell CC of the target wordline.

In general, the time allocated for an RMW operation is shorter than the time allocated for a general write or read operation. The row hammer management circuit 500 according to an example embodiment uses the target column selection line as a count column selection line, and thus may reliably perform an RMW operation even for a short period of time.

In addition, the memory device 200 according to an example embodiment may set a count column selection line among the plurality of column selection lines CSL1 to CSLn, rather than arranging count column selection lines in an additional space. An additional space for arranging the column selection line is not required, so that the memory device 200 according to an example embodiment may significantly reduce an increase in area due to row hammer management.

Before entering the count column selection line setting mode, the plurality of column selection lines CSL1 to CSLn may be allocated as a normal region for storing normal data. When a target column selection line, among the plurality of column selection lines CSL1 to CSLn, is set as a count column selection line, originally allocated normal data is unable to be stored in a memory cell connected to the target column selection line.

The memory device 200 according to an example embodiment may map at least one target column selection line, selected as a count column selection line, to another column selection line to store normal data instead of the target column selection line set as the count column selection line. Accordingly, the normal data may be stored or relocated in the another column selection line.

As a more detailed example, referring to FIG. 1, memory cells connected to the plurality of column selection lines CSL1 to CSLn of the first bank array BA1 may be initially set to store normal data. Then, the third column selection line CSL3, a target column selection line, among a plurality of column selection lines CSL1 to CSLn of the first bank array BA1, may be set as a count column selection line.

Count data of row accesses needs to be stored in memory cells of the third column selection line CSL3, so that the normal data allocated to the third column selection line CSL3 is unable to be stored in the third column selection line CSL3. The memory device 200 according to an example embodiment may map the third column selection line CSL3 to another column selection line. Accordingly, even when there is a write request for normal data to the third column selection line CSL3 selected as a count column selection line or a read request to the third column selection line CSL, the memory device 200 according to an example embodiment may reliably store the normal data in memory cells of the another column selection line mapped to the count column selection line or read the normal data stored in the memory cells of the another column selection line.

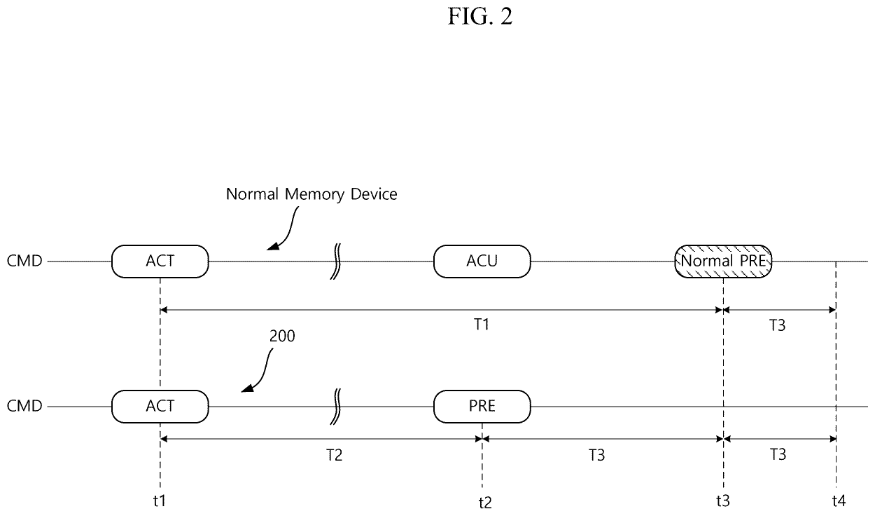

FIG. 2 is a diagram illustrating execution time of an RMW operation according to an example embodiment. For ease of description, an example is provided in which both a typical memory device and the memory device 200 according to an example embodiment (see FIG. 1) receive an active command ACT at first time point t1. Also, an example is provided in which both the typical memory device and the memory device 200 according to an example embodiment should complete a precharge operation by fourth time point t4.

Referring to FIG. 2, a typical memory device that does not support an RMW operation receives an active command ACT at first time point t1 and performs a write operation or a read operation for a first time T1. Then, the typical memory device receives a precharge command Normal PRE at third time point t3 and performs a precharge operation for a third time T3.

The memory device 200 according to an example embodiment that supports an RMW operation may receive an active command ACT at first time point t1 and perform a write operation or a read operation for a second time T2. Then, the memory device 200 may receive a precharge command PRE at second time point t2, earlier than third time point t3, and perform an RMW operation for a third time T3. The third time T3 during which the RMW operation is performed may be relatively shorter than the first time T1 during which a typical write operation or read operation is performed. Accordingly, when an RMW operation is performed for the third time T3 using a typical column selection line, an error rate of the RMW operation may increase.

The memory device 200 according to an example embodiment may select a target column selection line having good writing characteristics and/or reading characteristics from among the plurality of column selection lines and perform an RMW operation using the selected target column selection line to reliably perform an RMW operation for a relatively short period of time.

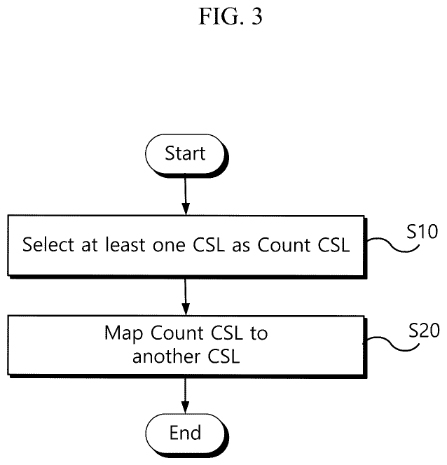

FIG. 3 is a flowchart illustrating an example of a count column selection line setting mode of the memory device 200 of FIG. 1.

In operation S10, among a plurality of column selection lines, at least one target column selection line may be selected as a count column selection line for row hammer management.

For example, the memory device 200 (see FIG. 1) may extract at least one target column selection line based on test results of writing characteristics and/or reading characteristics for each of the plurality of column selection lines. The memory device 200 may set at least one target column selection line as a count column selection line used for an RMW operation. Accordingly, the RMW operation may be reliably performed even for a short period of time.

In operation S20, the at least one target column selection line selected as the count column selection line may be mapped to another column selection line.

For example, the memory device 200 may map the at least one target column selection line, selected as the count column selection line, to another column selection line for data relocation. For example, the memory device 200 may map a target column selection line, set as a count column selection line in which normal data is unable to be stored, to another column selection line. Accordingly, when there is a write request for normal data to the target column selection line, the corresponding normal data may be stored in memory cells of the another column selection line mapped to the count column selection line.

As described above, the memory device 200 according to an example embodiment may extract a target column selection line from a plurality of column selection lines and set the target column selection line as a count column selection line. Accordingly, the memory device 200 according to an example embodiment may reliably perform an operation to prevent row hammer. In addition, an additional space for arranging the column selection line is not required, so that an increase in area may be significantly reduced.

Hereinafter, various examples of the memory system 10 of FIG. 1 will be described in more detail.

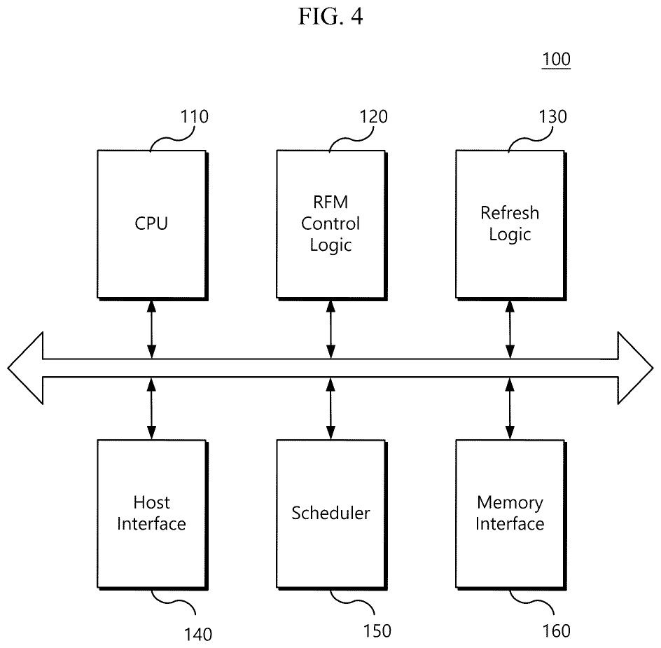

FIG. 4 is a block diagram illustrating an example of the configuration of a memory controller 100 according to an example embodiment. The memory controller 100 of FIG. 4 may correspond to, for example, the memory controller 100 of FIG. 1.

Referring to FIG. 4, the memory controller 100 may include a CPU 110, a refresh management (RFM) control logic 120, a refresh logic 130, a host interface 140, a scheduler 150, and a memory interface 160, which are interconnected via a bus.

The CPU 110 may control the overall operation of the memory controller 100. For example, the CPU 110 may control each of the RFM control logic 120, the refresh logic 130, the host interface 140, the scheduler 150, and the memory interface 160.

The RFM control logic 120 may generate an RFM command associated with row hammer. For example, when it is determined that an access is concentrated on a specific wordline (i.e., an access is repeatedly made on the specific wordline in a predetermined time duration), the RFM control logic 120 may generate a command to refresh memory cells connected to wordlines adjacent to the specific wordline on which the access is concentrated.

The refresh logic 130 may generate commands to perform a normal refresh operation on a plurality of wordlines of the memory device 200. For example, the refresh logic 130 may generate an auto-refresh command to sequentially refresh a plurality of wordlines according to a refresh period.

The host interface 140 may perform interfacing with a host. The memory interface 160 may perform interfacing with the memory device 200.

The scheduler 150 may manage scheduling and transmission of sequences of commands generated in the memory controller 100.

In an example embodiment, the RFM control logic 120 may determine whether an access is concentrated to a specific wordline, based on count data stored in a count cell of the target column selection line that is a count column selection line. Among the plurality of column selection lines, the target column selection line is set as a count column selection line, so that the number of accesses to each wordline may be precisely managed. As a result, reliability of the refresh operation may be improved.

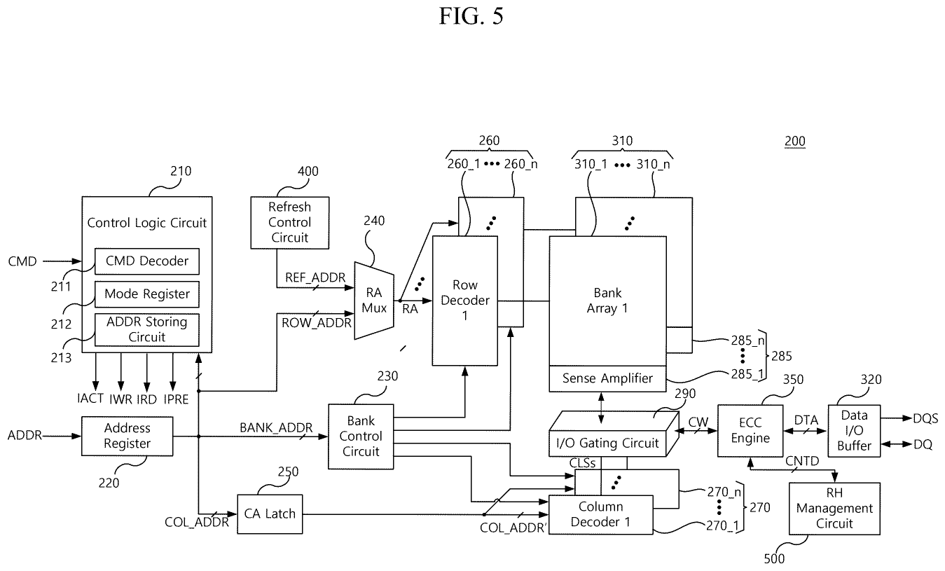

FIG. 5 is a block diagram illustrating an example of a memory device 200 according to an example embodiment. The memory device 200 of FIG. 5 may correspond to the memory device 200 of FIG. 1.

Referring to FIG. 5, the memory device 200 may include a control logic circuit 210, an address register 220, a bank control logic 230, a refresh control circuit 400, a row address multiplexer 240, a column address latch 250, a row decoder group 260, a column decoder group 270, a memory cell array 310, a sense amplifier circuit 285, an input/output gating circuit 290, an Error correcting code (ECC) engine 350, a data input/output buffer 320, and a row hammer management circuit 500.

The memory cell array 310 may include a plurality of bank arrays 310_1 to 310_n. Each of the plurality of bank arrays 310_1 to 310_n may include a plurality of memory cells. For example, each of the plurality of memory cells may be formed at an intersection of a corresponding wordline and a corresponding bitline.

The row decoder group 260 may include a plurality of row decoders 260_1 to 260_n. Each of the plurality of row decoders 260_1 to 260_n may be connected to a corresponding bank array among the plurality of bank arrays 310_1 to 310_n.

The sense amplifier circuit 285 may include a plurality of sense amplifiers 285_1 to 285_n. Each of the plurality of sense amplifiers 285_1 to 285_n may be connected to a corresponding bank array among the plurality of bank arrays 310_1 to 310_n.

The column decoder group 270 may include a plurality of column decoders 270_1 to 270_n. Each of the plurality of column decoders 270_1 to 270_n may be connected to a corresponding bank array, among the plurality of bank arrays 310_1 to 310_n, through column selection lines CLSs.

In an example embodiment, each of the plurality of column decoders 270_1 to 270_n may select a target column selection line among a plurality of column selection lines CLSs. The selected target column selection line may be used as a count column selection line. For example, count data that is the number of accesses to each wordline may be stored in memory cells connected to the selected target column selection line. The number of accesses to each wordline may be managed using the target column selection line, so that an RMW operation may be reliably performed to prevent row hammer. For example, based on the count data stored in the memory cells connected to the selected target column selection line, memory cells of wordlines adjacent to a specific wordline may be refreshed to avoid data loss due to row hammer of the specific wordline.

The address register 220 may receive an address ADDR, including a bank address BANK_ADDR, a row address ROW_ADDR, and a column address COL_ADDR, from the memory controller 100. The address register 220 may provide the received bank address BANK_ADDR to the bank control logic 230, the received row address ROW_ADDR to the row address multiplexer 240, and the received column address COL_ADDR to the column address latch 250. In addition, the address register 220 may provide the bank address BANK_ADDR and the row address ROW_ADDR to the row hammer management circuit 500 and the RMW driver 600.

The bank control logic 230 may generate bank control signals in response to the bank address BANK_ADDR. For example, a row decoder corresponding to the bank address BANK_ADDR, among the plurality of row decoders 260_1 to 260_n, may be activated in response to the bank control signals. A column decoder corresponding to the bank address BANK_ADDR, among the plurality of column decoders 270_1 to 270_n, may be activated in response to the bank control signals.

The row address multiplexer 240 may receive a row address ROW_ADDR from the address register 220 and a refresh row address REF_ADDR from the refresh control circuit 400. The row address multiplexer 240 may selectively output the row address ROW_ADDR or the refresh row address REF_ADDR as a row address RA. The row address RA output from the row address multiplexer 240 may be applied to each of the plurality of row decoders 260_1 to 260_n.

The refresh control circuit 400 may sequentially increase or decrease the refresh row address REF_ADDR in response to refresh signals from the control logic circuit 210 in a normal refresh mode.

In a hammer refresh mode, the refresh control circuit 400 may receive a hammer address HADDR. The refresh control circuit 400 may output addresses of wordlines adjacent to an intensively accessed wordline as the refresh row address REF_ADDR, based on the hammer address HADDR. For example, the hammer address HADDR may correspond to a row address subject to the row hammer (i.e., repeatedly accessed), and the refresh row address REF_ADDR may correspond to a row address adjacent to the hammer address HADDR.

A row decoder selected by the bank control logic 230, among the plurality of row decoders 260_1 to 260_n, may activate a wordline corresponding to the row address RA output from the row address multiplexer 240. For example, the selected row decoder may apply a wordline driving voltage to the wordline corresponding to the row address.

The column address latch 250 may receive a column address COL_ADDR from the address register 220 and temporarily store the received column address COL_ADDR. For example, in burst mode, the column address latch 250 may gradually or consecutively increase the received column address COL_ADDR. The column address latch 250 may apply a temporarily stored or gradually increased column address COL_ADDR′ to each of the plurality of column decoders 270_1 to 270_n.

The column decoder activated by the bank control logic 230, among the plurality of column decoders 270_1 to 270_n, may activate a sense amplifier corresponding to the bank address BANK_ADDR and the column address COL_ADDR through the input/output gating circuit 290.

The input/output gating circuit 290 may include circuits for gating input/output data. In addition, the input/output gating circuit 290 may include data latches which store codewords output from the plurality of bank arrays 310_1 to 310_n, and write drivers writing data in the plurality of bank arrays 310_1 to 310_n.

In an example embodiment, a codeword CW read from a selected bank array, among the plurality of bank arrays 310_1 to 310_n, may be detected by a sense amplifier corresponding to the selected bank array and stored in data latches of the input/output gating circuit 290 during a read operation. Also, the codeword CW stored in the data latches may be subjected to ECC decoding by the ECC engine 350 and then provided as data DTA to the data input/output buffer 320. The data input/output buffer 320 may generate a data signal DQ based on the data DTA and provide the data signal DQ to the memory controller 100 along with a strobe signal DQS. For example, the data signal DQ may be synchronized with the strobe signal DQS.

In an example embodiment, data DTA to be written in a selected bank array, among the plurality of bank arrays 310_1 to 310_n, may be received as a data signal DQ by the data input/output buffer 320 during a write operation. The data input/output buffer 320 may convert the data signal DQ into data DTA and provide the data DTA to the ECC engine 350. The ECC engine 350 may generate parity bits (or parity data) based on the data DTA and provide a codeword CW, including the data DTA and the parity bits, to the input/output gating circuit 290. The input/output gating circuit 290 may write the codeword CW in the selected bank array.

The data input/output buffer 320 may convert the data signal DQ into data DTA and provide the data DTA to the ECC engine 350 during a write operation. The data input/output buffer 320 may convert the data DTA, provided from the ECC engine 350, into a data signal DQ during a read operation.

The ECC engine 350 may perform ECC encoding on the data DTA during a write operation. The ECC engine 350 may perform ECC decoding on the codeword CW during a read operation. Also, the ECC engine 350 may perform ECC encoding and ECC decoding on count data CNTD provided from the row hammer management circuit 500. In an embodiment, the count data CNTD may store data representing a number of accesses to a specific wordline which is selected for a read operation or a write operation.

The row hammer management circuit 500 may manage the number of accesses to each of the plurality of wordlines. For example, when a target wordline is activated, the row hammer management circuit 500 may receive count data CNTD corresponding to the target wordline from the ECC engine 350, update the received count data CNTD (e.g., increase a value of the count data CNTD by one), and provide the updated count data CNTD to the ECC engine 350.

The control logic circuit 210 may control the operation of the memory device 200. For example, the control logic circuit 210 may generate control signals such that the memory device 200 performs a write operation, a read operation, a normal refresh operation, and a hammer refresh operation. The control logic circuit 210 may include a command decoder 211, a mode register set (MRS) 212, and an address storage circuit 213 storing address information of a target column selection line.

The command decoder 211 may decode a command CMD received from the memory controller 100. The command decoder 211 may decode the command CMD to generate internal command signals such as an internal active signal IACT, an internal precharge signal IPRE, an internal read signal IRD, and an internal write signal IWR. In addition, the command decoder 211 may decode a chip select signal and a command/address signal to generate control signals corresponding to the command CMD.

The mode register set 212 may set an operating mode of the memory device 200.

In an example embodiment, the mode register set 212 may support a count column selection line setting mode. In the count column selection line setting mode, at least one target column selection line may be extracted from a plurality of column selection lines of a bank array allocated to store normal data. A portion or all of the extracted at least one target column selection line may be set as a count column selection line for storing count data CNTD. Also, the target column selection line set as a count column selection line may be mapped to another column selection line. Accordingly, normal data requested to be written in the target column selection line set as a count column selection line may be reliably stored in the another column selection line.

In an example embodiment, the mode register set 212 may support a count column selection line repair mode. For example, when a count column selection line fails, the count column selection line repair mode may be entered or activated. In the count column selection line repair mode, at least one target column selection line may be re-selected from a plurality of column selection lines of the bank array. The re-selected at least one target column selection line may be set as a new count column selection line.

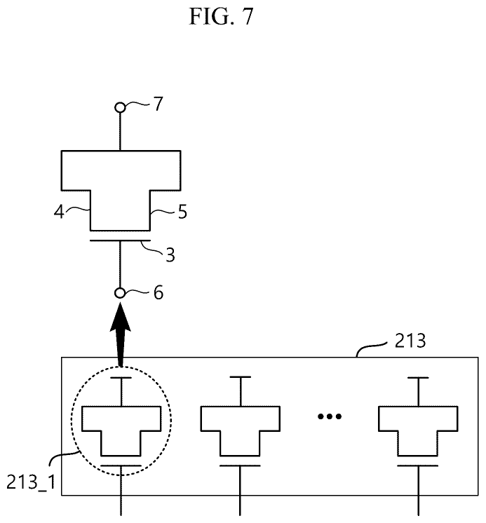

The address storage circuit 213 may store address information of a target column select address set as a count column selection line. Also, according to an example embodiment, the address storage circuit 213 may additionally store address information of another column selection line to store normal data, instead of the target column select address set as a count column selection line. In an embodiment, the address storage circuit 213 may store an address mapping information between the target column select address and the another column selection line, and thus when receiving the target column select address in a read operation or a write operation, the address storage circuit 213 may convert the target column select address into the another column selection line (see FIG. 7)

In an example embodiment, another column selection line for storing normal data instead of the target column selection line set as a count column selection line may be in a predetermined state. The address storage circuit 213 may store only address information of the target column select address.

In an example embodiment, among the plurality of column selection lines, a column selection line to store normal data may be selected instead of the target column selection line set as a count column selection line. The address storage circuit 213 may store address information of the target column select address set as a count column selection line and address information of the another column selection line mapped thereto.

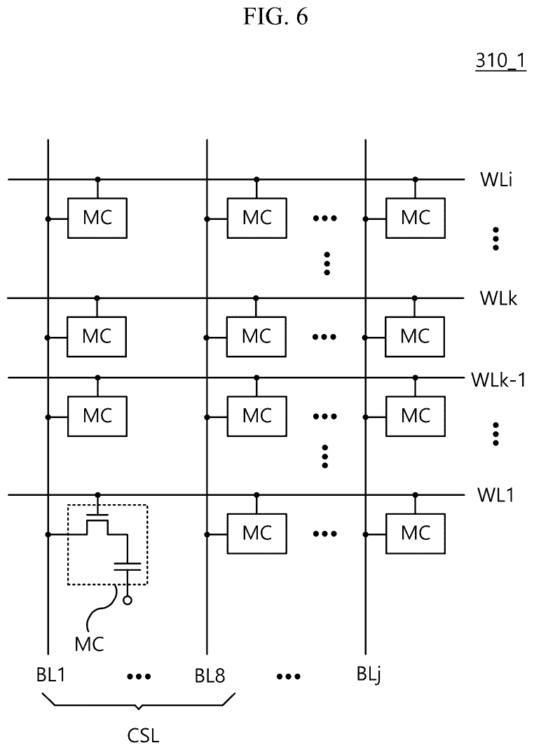

FIG. 6 is a diagram illustrating an example of a bank array according to an example embodiment. A bank array 310_1 of FIG. 6 may correspond to the first bank array 310_1 of FIG. 5.

Referring to FIG. 6, the first bank array 310_1 may include a plurality of wordlines WL1 to WLi, a plurality of bitlines BL1 to BLj, and a plurality of memory cells MC disposed at intersections between the wordlines WL1 to WLi and the bitlines BL1 to BLj.

In an example embodiment, each of the memory cells MC may be a DRAM cell. For example, each of the memory cells MC may include a cell transistor, connected to a wordline and a bitline, and a cell capacitor connected to the cell transistor.

A single column selection line CSL may be electrically connected to a plurality of bitlines. For example, a single column selection line CSL may be electrically connected to eight bitlines. In this case, 8 bits of data may be read from or written in the memory cells MC through a single wordline and a single column selection line CSL.

FIG. 7 is a diagram illustrating an example of the address storage circuit 213 of FIG. 5. FIG. 7 illustrates an example in which the address storage circuit 213 is implemented using an antifuse array.

Referring to FIG. 7, the address storage circuit 213 may be implemented as an antifuse array including a plurality of antifuses 213_1.

An antifuse 213_1 may be a resistive element having electrical characteristics opposite to those of a fuse element. The antifuse 213_1 may have a high resistance value in an unprogrammed state and a low resistance value in a programmed state.

The antifuse 213_1 may generally be configured with a dielectric inserted between conductors. A program operation may be performed on the antifuse 213_1 by applying a high voltage through conductors at opposite ends of the antifuse 213_1 to break down a dielectric between the two conductors. As a result of the program operation, the conductors at the opposite ends of the antifuse 213_1 may be short-circuited, and thus the antifuse 213_1 may have a low resistance value.

For example, the antifuse 213_1 may include a depletion-type MOS transistor in which a source 4 and a drain 5 are connected to each other. In an initial state, resistance between a first node 6 connected to a gate electrode 3 and a second node 7 commonly connected to the source 4 and the drain 5 may be significantly high because the first node 6 and the second node 7 are separated by a gate oxide. This state may be set as an unprogrammed state.

A breakdown voltage may be applied between the first node 6 and the second node 7 to break down the gate oxide of the antifuse 213_1. When the gate oxide is broken down, the resistance between the first node 6 and the second node 7 may be decreased. This state may be set as a programmed state.

As described above, the address storage circuit 213 according to an example embodiment may be implemented to include antifuses such that address information of a count column selection line may be safely stored.

For example, the gate oxide of the antifuse may be broken down, allowing the address storage circuit 213 to store address information of a good column selection line set as a count column selection line among a plurality of column selection lines.

Alternatively, for example, the gate oxide of the antifuse may be broken down, allowing the address storage circuit 213 to store address information of a target column selection line set as a count column selection line among a plurality of column selection lines, as well as address information of another column selection line to store normal data instead of the target column selection line.

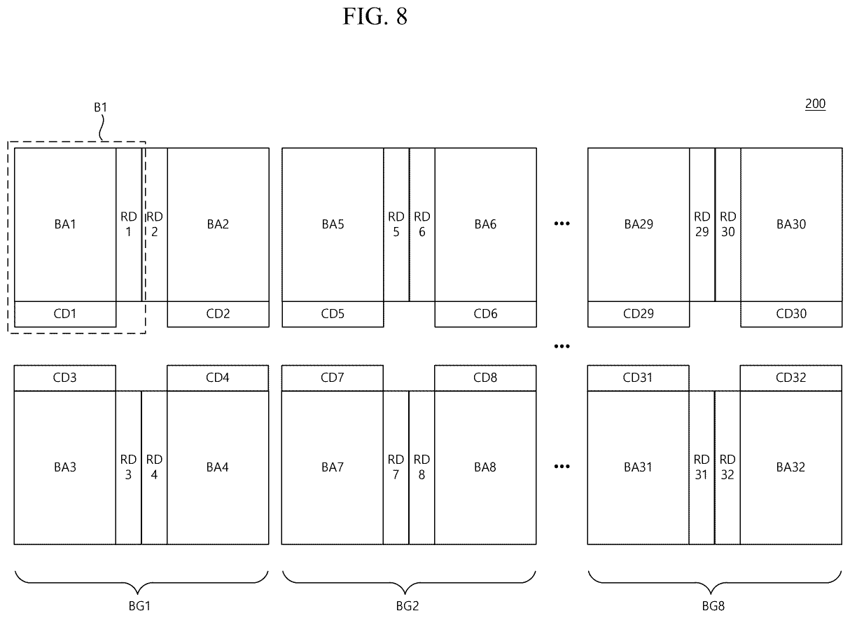

FIG. 8 is a diagram illustrating an example of the memory device according to an example embodiment. FIG. 8 illustrates an example in which a bank array, and a row decoder and a column decoder corresponding to the bank array are disposed. The memory device 200 of FIG. 8 may correspond to, for example, the memory device 200 of FIGS. 1 and 5. For ease of description, an example is provided in which the memory device 200 includes 32 bank arrays and a single bank group BG includes 4 bank arrays.

Referring to FIG. 8, a first bank group BG1 may include first to fourth bank arrays BA1 to BA4. For example, the first and second bank arrays BA1 and BA2 may be disposed adjacent to each other above a substrate, not illustrated, and the third and fourth bank arrays BA3 and BA4 may be disposed adjacent to each other below the substrate.

A first row decoder RD1 and a first column decoder CD1 may correspond to the first bank array BA1, and a second row decoder RD2 and a second column decoder CD2 may correspond to the second bank array BA2. A third row decoder RD3 and a third column decoder CD3 may correspond to the third bank array BA3, and a fourth row decoder RD4 and a fourth column decoder CD4 may correspond to the fourth bank array BA4.

The first and second row decoders RD1 and RD2 may be disposed between the first bank array BA1 and the second bank array BA2 adjacent to each other. The third and fourth row decoders RD3 and RD4 may be disposed between the third bank array BA3 and the fourth bank array BA4 adjacent to each other. However, this is only an example, and the bank array, the row decoder, and the column decoder may be disposed in various forms according to example embodiments.

Similarly, the second bank group BG2 may include fifth to eighth bank arrays BA5 to BA8, and fifth and sixth row decoders RD5 and RD6 may be disposed between the fifth bank array BA5 and the sixth bank array BA6 adjacent to each other and seventh and eighth row decoders RD7 and RD8 may be disposed between the seventh bank array BA7 and the eighth bank array BA8 adjacent to each other. Similarly, the eighth bank group BG8 may include 29th to 32nd bank arrays BA29 to BA32, and row decoders may be disposed between adjacent bank arrays.

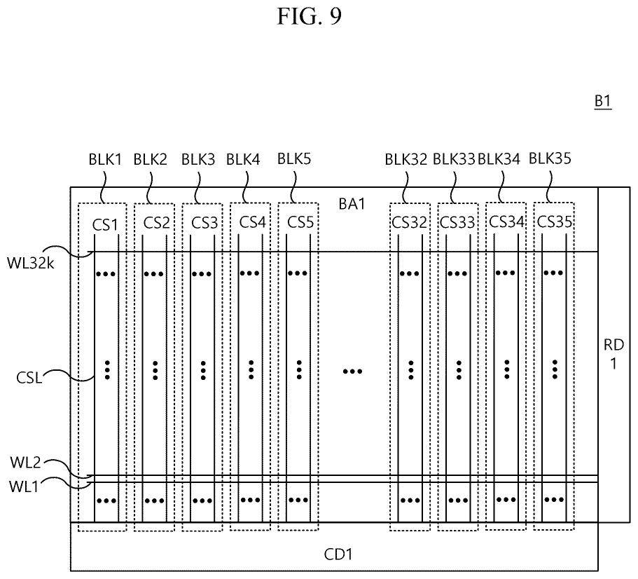

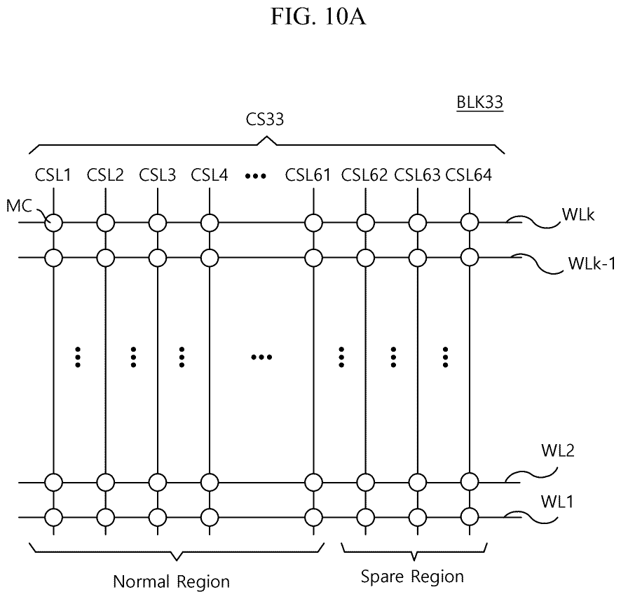

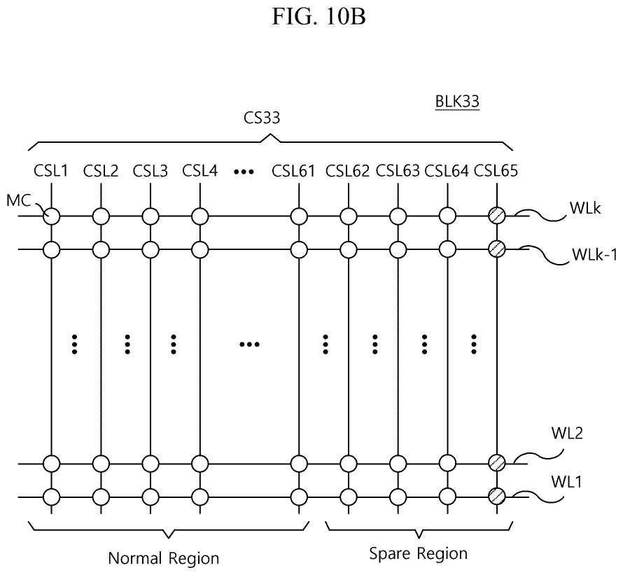

FIG. 9 is a diagram illustrating an example of a bank according to an example embodiment. A first bank B1 of FIG. 9 may correspond to one of the banks described in FIGS. 1 and 8. FIGS. 10A and 10B are diagrams illustrating more detailed examples of blocks included in a bank of FIG. 9. For example, a 33rd block BLK33 of FIG. 9 is illustrated in FIGS. 10A and 10B. For ease of description, in FIGS. 9, 10A, and 10B, an example is provided in which the first bank B1 includes 35 blocks, and each of the 35 block includes a normal region for storing normal data and a spare region.

Referring to FIG. 9, the first bank B1 may include a first bank array BA1, a first row decoder RD1, and a first column decoder CD1.

The first bank array BA1 may include a plurality of blocks BLK1 to BLK35. Each of the plurality of blocks BLK1 to BLK35 may be connected to wordlines WL1 to WLk. Each of the plurality of blocks BLK1 to BLK35 may be connected to a corresponding column selection line group among column selection line groups CSI to CS35. The plurality of blocks BLK1 to BLK35 may perform write or read operations in parallel. For example, data may be stored in the plurality of blocks BLK1 to BLK35 simultaneously, or data may be read from the plurality of blocks BLK1 to BLK35 simultaneously.

Each of the plurality of column selection line groups CSI to CS5 may include a plurality of column selection lines. For example, each column selection line group may include a plurality of column selection lines, and a portion of the plurality of column selection lines may be allocated to the normal region, and the remaining column selection lines may be allocated to the spare region.

In an example embodiment, a portion of the plurality of blocks BLK1 to BLK35 may be set to include count cells. For example, at least one of the plurality of blocks BLK1 to BLK35 may be set to include a count column selection line.

For example, the first bank array BA1 may include three count column selection lines. For example, among the plurality of blocks BLK1 to BLK35, a block that is physically adjacent to a circuit that performs an RMW operation may be configured to include a count column selection line. For example, among the plurality of blocks BLK1 to BLK35, each of the 33rd to 35th blocks BLK33 to BLK35 may be configured to include a single count column selection line. Alternatively, one of the plurality of blocks BLK1 to BLK35 may be configured to include three count column selection lines.

For example, a more detailed description is now provided with reference to the 33rd block BLK33 illustrated in FIG. 10A. The 33rd block BLK33 may include a 33rd column selection line group CS33, and the 33rd column selection line group CS33 may include 64 column selection lines CSL1 to CSL64. Some column selection lines CSL1 to CSL61 may be allocated to a normal region for storing normal data, and the other column selection lines CSL62 to CSL64 may be allocated to a spare region for storing ECC parity bits, flag data, metadata, or the like.

In an example embodiment, the 33rd block BLK33 may be configured to include at least one count column selection line. At least one target column selection line may be selected from among the column selection lines CSL1 to CSL61 of the normal region, and the selected target column selection line may be set as a count column selection line. Among the column selection lines CSL62 to CSL64 of the spare region, at least one column selection line may store normal data instead of the target column selection line set as a count column selection line.

Among the column selection lines CSL62 to CSL64 of the spare region, at least one column selection line stores normal data instead of the target column selection line, so that column selection lines provided in the spare region may be insufficient. In this regard, as illustrated in FIG. 10B, the 33rd block BLK33 may further include a 65th column selection line CSL65, and the 62nd to 65th column selection lines CSL62 to CSL65 may be allocated to the spare region.

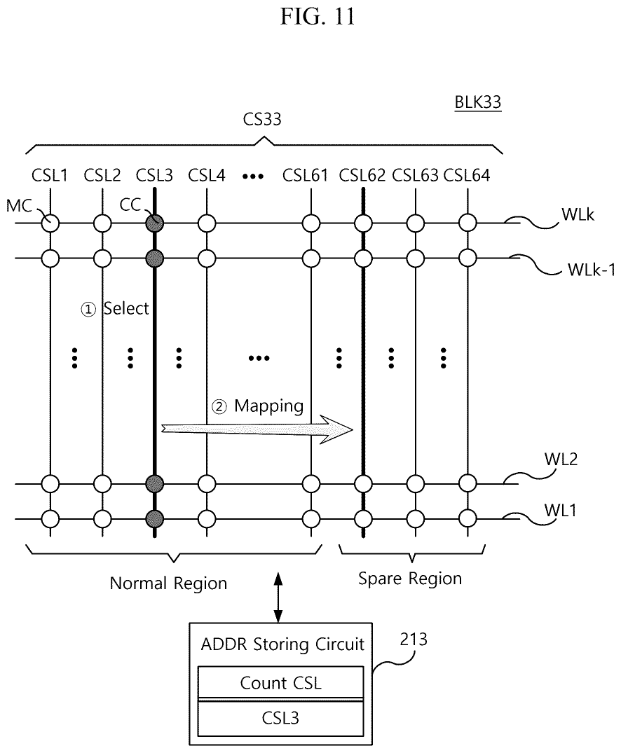

FIG. 11 is a diagram illustrating an example of an operation of setting a count column selection line according to an example embodiment. FIG. 11 illustrates an example in which a specific column selection line, among column selection lines of a spare region, is fixedly mapped to a target column selection line. For ease of description, in FIG. 11, an example is provided in which a single column selection line is selected as a count column selection line from a 33rd column selection line group CS33 of the 33rd block BLK33. Also, an example is provided in which a 62nd column selection line CSL62 is fixedly mapped to a selected target column selection line.

Referring to FIG. 11, a target column selection line may be selected from among column selection lines CSL1 to CSL61 of a normal region of the 33rd block BLK33. For example, the third column selection line CSL3 may be selected as a target column selection line. The selected third column selection line CSL3 may be set as a count column selection line. Accordingly, memory cells connected to the third column selection line CSL3 may be used as count cells CC storing an active count of corresponding wordlines, respectively.

The address storage circuit 213 may store address information of the third column selection line CSL3 set as the count column selection line. For example, the address storage circuit 213 may be implemented using an antifuse. Accordingly, the address information of the count column selection line may be stored.

Then, the third column selection line CSL3 may be mapped to the 62nd column selection line CSL62. Accordingly, when there is a request to write normal data in memory cells of the third column selection line CSL3, memory cells of the 62nd column selection line CSL62 may store the normal data instead of the third column selection line CSL3.

The 62nd column selection line CSL62 may be provided to fixedly replace the count column selection line using the address storage circuit 213. As illustrated in FIG. 11, the address storage circuit 213 may not store mapping information between the third column selection line CSL3 and the 62nd column selection line CSL62.

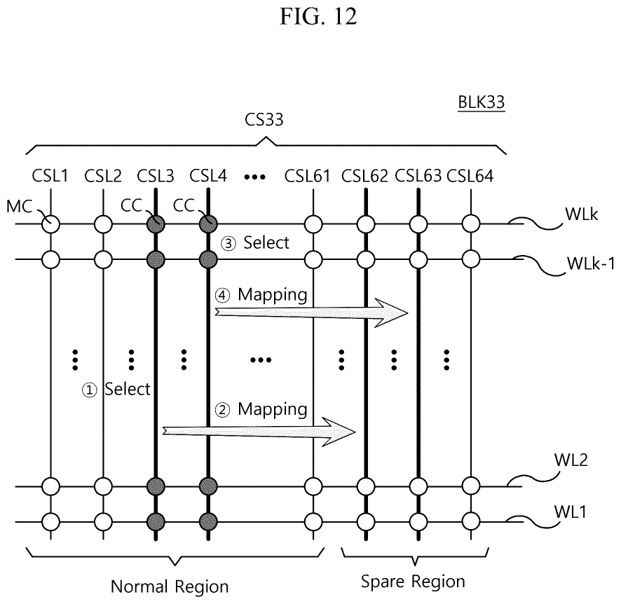

FIG. 12 is a diagram illustrating an example of an operation of setting a count column selection line according to an example embodiment. For ease of description, in FIG. 12, an example is provided in which two column selection lines are selected as count column selection lines from a 33rd column selection line group CS33 of a 33rd block BLK33. The operation of setting the count column selection line of FIG. 12 is similar to that of FIG. 11. Therefore, redundant descriptions will be omitted to avoid repetition.

Referring to FIG. 12, a third column selection line CSL3 may be selected as a target column selection line from among column selection lines CSL1 to CSL61 of a normal region of the 33rd block BLK33. The selected third column selection line CSL3 may be set as a count column selection line. Then, the third column selection line CSL3 may be mapped to a 62nd column selection line CSL62 of a spare region.

A fourth column selection line CSL4 may be selected as a target column selection line from among the column selection lines CSL1 to CSL61 of the normal region of the 33rd block BLK33. The selected fourth column selection line CSL4 may be set as a count column selection line. Then, the fourth column selection line CSL4 may be mapped to a 63rd column selection line CSL63 of the spare region.

As described above, according to an example embodiment, a plurality of target column selection lines may be selected from among a plurality of column selection lines of a normal region of each block, and the selected target column selection lines may be set as count column selection lines.

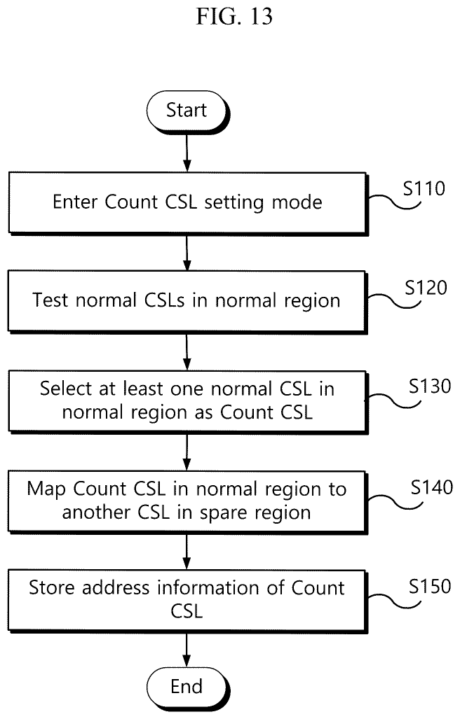

FIG. 13 is a flowchart illustrating an example of an operation of setting a count column selection line according to an example embodiment.

In operation S110, a memory device may enter a count column selection line setting mode.

In operation S120, the memory device may perform a test operation on a plurality of column selection lines of a normal region.

For example, the memory device may perform a test operation on each of the plurality of columns of the normal region to check a target column selection line having good writing characteristics and/or reading characteristics.

In operation S130, the memory device may select a target column selection line to be used as a count column selection line from among the plurality of column selection lines of the normal region based on a test result of the test operation performed in operation S120.

For example, as illustrated in FIG. 11, when a single block is configured to include a single count column selection line, the memory device may select a single target column selection line from among the plurality of column selection lines of the normal region and set the selected target column selection line as a count column selection line.

For example, as illustrated in FIG. 12, when a single block is configured to include at least two count column selection lines, the memory device may select at least two target column selection lines from among the plurality of column selection lines of the normal region and set each of the selected at least two target column selection lines as a count column selection line.

In operation S140, the memory device may map the count column selection line of the normal region to another column selection line of the spare region.

For example, as illustrated in FIGS. 11 and 12, a column selection line of the spare region to replace the count column selection line may be predetermined. The memory device may map the count column selection line to the column selection line of the spare region. Accordingly, when there is a request to write normal data in the count column selection line, the normal data may be stored in the column selection line of the spare region.

In operation S150, the memory device may store address information of the count column selection line.

For example, as illustrated in FIG. 11, the memory device includes an address storage circuit 213, and the address storage circuit 213 may store an address of the target count column selection line set as the count column selection line.

As described above, a target column selection line may be selected from among the plurality of column selection lines of the normal region and the selected target column selection line may be used as a count column selection line. Therefore, the memory device according to an example embodiment may reliably perform an RMW operation to prevent row hammer.

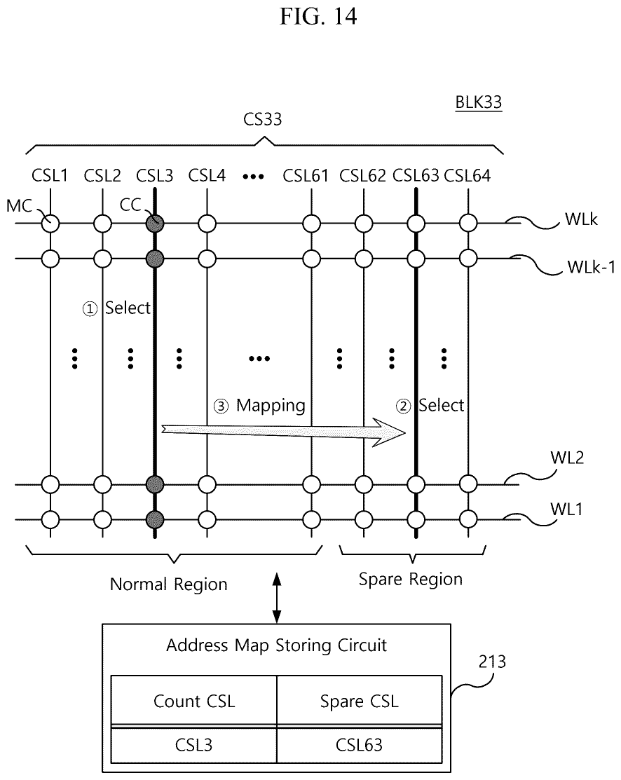

FIG. 14 is a diagram illustrating an example of an operation of setting a count column selection line according to an example embodiment. FIG. 14 illustrates an example in which among column selection lines of a spare region, a column selection line to be mapped to the count column selection line is not fixed. The operation of the count column selection line of FIG. 14 is similar to the operation of FIG. 11. Therefore, redundant descriptions will be omitted to avoid repetition.

Referring to FIG. 14, a target column selection line may be selected from among column selection lines CSL1 to CSL61 of a normal region of a 33rd block BLK33, and the selected target column selection line may be set as a count column selection line. For example, a third column selection line CSL3 may be set as a count column selection line.

Then, a column selection line to store normal data instead of the count column selection line may be selected from among column selection lines CSL62 to CSL64 of the spare region. For example, a 63rd column selection line CSL63 of the spare region may be selected as the column selection line to store the normal data instead of the count column selection line.

Then, the third column selection line CSL3 may be mapped to the 63rd column selection line CSL63. Accordingly, when there is a request to write normal data in the third column selection line CSL3, memory cells of the 63rd column selection line CSL63 may store the normal data instead of the third column selection line CSL3.

The address storage circuit 213 may store address information of the target column selection line in the normal region to be used as a count column selection line and mapping information of the column selection line in the spare region mapped thereto. For example, the address storage circuit 213 may store address information of the third column selection line CSL3 in the normal region to be used as a count column selection line and address information of the 63rd column selection line CSL63 in the spare region mapped thereto.

As described above, according to an example embodiment, a target column selection line to be used as a count column selection line may be selected from the normal region, and a column selection line to store normal data instead of the count column selection line may be selected from the spare region.

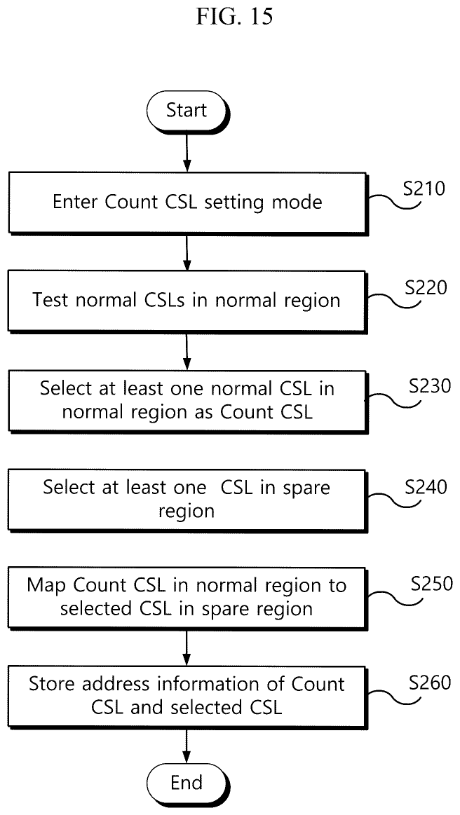

FIG. 15 is a flowchart illustrating an example of an operation of setting a count column selection line according to an example embodiment. The operation of setting the count column selection line of FIG. 15 is similar to that of FIG. 13. Therefore, redundant descriptions will be omitted to avoid repetition.

In operation S210, a memory device may enter a count column selection line setting mode.

In operation S220, the memory device may perform a test operation on a plurality of column selection lines of a normal region.

In operation S230, the memory device may select a target column selection line to be used as a count column selection line from among the plurality of column selection lines of the normal region based on a test result of the test operation performed in operation S220.

In operation S240, the memory device may select a column selection line to store normal data requested to be written in a column selectin line, instead of the count column selection line, from among a plurality of column selection lines of a spare region.

For example, as illustrated in FIG. 14, a column selection line of the spare region to replace the count column selection line may not be predetermined. The memory device may select a column selection line to replace the count column selection line from among the plurality of column selection lines of the spare region.

In operation S250, the memory device may map the count column selection line of the normal region to the selected column selection line of the spare region.

In operation S260, the memory device may store address information of the count column selection line of the normal region and address information of the column selection line of the spare region mapped thereto.

For example, as illustrated in FIG. 14, the memory device includes an address storage circuit 213, and the address storage circuit 213 may store address information of the target column selection line to be used as a count column selection line and address information of the column selection line of the spare region mapped to the target column selection line.

As described above, a target column selection line may be selected from among the plurality of column selection lines of the normal region and may be used as a count column selection line. A column selection line to store normal data instead of the count column selection line may be selected from the spare region. Therefore, the memory device according to an example embodiment may reliably perform an RMW operation to prevent row hammer.

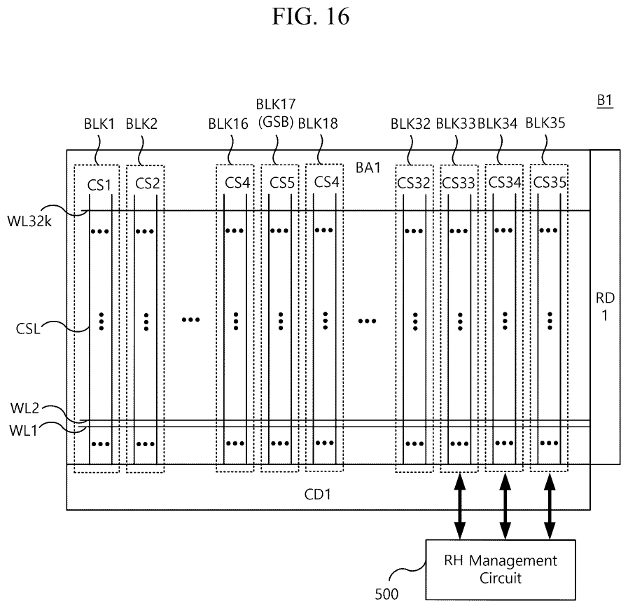

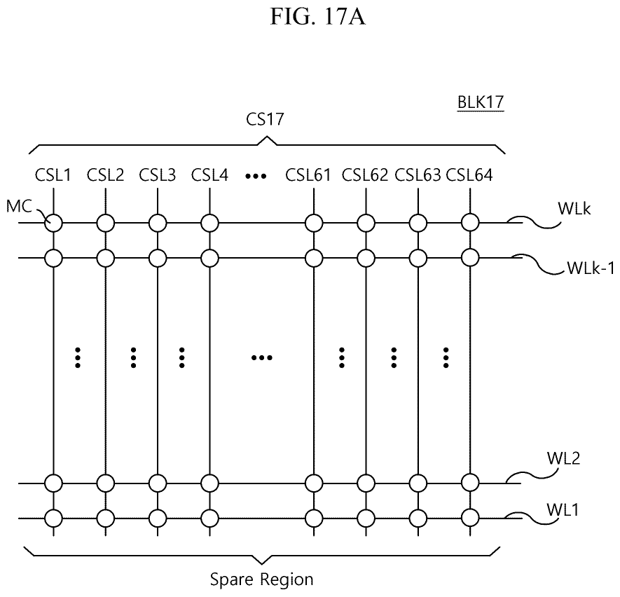

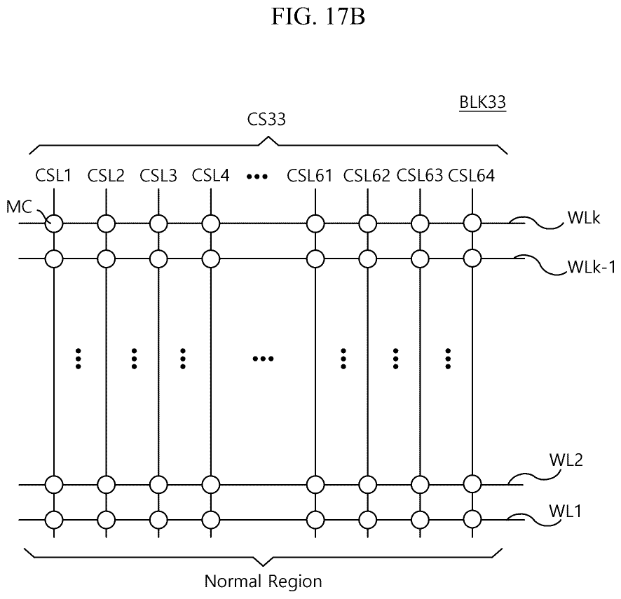

FIG. 16 is a diagram illustrating an example of a bank according to an example embodiment. FIG. 17A is a diagram illustrating a more detailed example of a global spare block among blocks of FIG. 16, and FIG. 17B is a diagram illustrating a more detailed example of a normal block among the blocks of FIG. 16.

In FIGS. 16, 17A, and 17B, an example is provided in which a 17th block BLK17 is a global spare block GSB and the remaining blocks are normal blocks. Also, in FIGS. 16, 17A, and 17B, an example is provided in which a first bank B1 includes 35 blocks and three count column selection lines need to be selected. Also, an example is provided in which a row hammer management circuit 500 performing an RMW operation is physically adjacent to 33rd to 35th blocks BLK33 to BLK35.

Banks and blocks of FIGS. 16, 17A, and 17B are similar to the banks and blocks of FIGS. 9, 10A, and 10B. Therefore, redundant descriptions will be omitted to avoid repetition.

Referring to FIG. 16, a first bank B1 may include a first bank array BA1, a first row decoder RD1, and a first column decoder CD1.

The first bank array BA1 may include a plurality of blocks BLK1 to BLK35. Each of the plurality of blocks BLK1 to BLK35 may be connected to wordlines WL1 to WLk.

Each of the plurality of blocks BLK1 to BLK35 may be connected to a corresponding column selection line group, among a plurality of column selection line groups CSI to CS35. Each of the plurality of column selection line groups CSI to CS5 may include a plurality of column selection lines.

Unlike the first bank of FIG. 9, at least one of the blocks BLK1 to BLK35 of a first bank B1 of FIG. 16 may be set as a global spare block GSB. The global spare block GSB may refer to a block of which all column selection lines are allocated to a spare region. For example, a 17th block BLK17 may be set as a global spare block GSB.

A more detailed description is now provided with reference to FIG. 17A. The 17th block BLK17 may include a 17th column selection line group CS17, and the 17th column selection line group CS17 may include 64 column selection lines CSL1 to CSL64. All of the column selection lines CSL1 to CSL64 of the 17th block BLK17 may be set as a spare region.

Among the blocks BLK1 to BLK35 of the first bank B1 of FIG. 16, the remaining blocks except for the global spare block may be set as normal blocks to store normal data. For example, except for the 17th block BLK17 that is the global spare block GSB, the remaining blocks BLK1 to BLK16 and BLK18 to BLK35 may be set as normal blocks.

A more detailed description is now provided with reference to FIG. 17B. A 33rd block BLK33 may include a 33rd column selection line group CS33, and the 33rd column selection line group CS33 may include 64 column selection lines CSL1 to CSL64. Column selection lines CSL1 to CSL64 of the 33rd block BLK33 may all be set as a normal region for storing normal data.

As described above, if a global spare block is included, even when there are a plurality of failed column selection lines in a single block, a repair operation may be performed on the plurality of failed column selection lines using the column selection lines of the global spare block GSB.

In an example embodiment, at least one of the plurality of blocks BLK1 to BLK35 may be configured to include a count column selection line. For example, considering that an RMW operation through the count column selection line needs to be performed for a relatively short time, a block physically adjacent to the row hammer management circuit 500 performing the RMW operation may be configured to include a count column selection line. For example, at least one of the blocks BLK1 to BLK35 adjacent to the row hammer management circuit 500 may be selected to include a count column selection line, since an RMW operation via the count column selection line is required to be completed in a relatively short time.

For example, the first bank array BA1 may be configured to include three count column selection lines. Among the plurality of blocks BLK1 to BLK35, 33rd to 35th blocks BLK33 to BLK35, which are physically closest to the row hammer management circuit 500, may each be configured to include a single count column selection line.

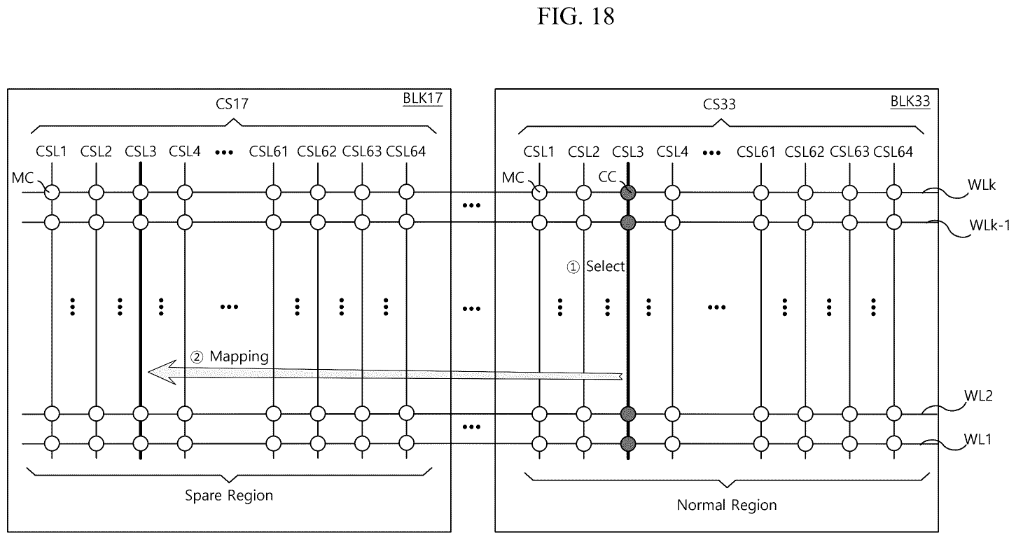

FIG. 18 is a diagram illustrating an example of an operation of setting a count column selection line according to an example embodiment. A 17th block BLK17 and a 33rd block BLK33 of FIG. 18 may correspond to the 17th block BLK17 and the 33rd block BLK33 of FIGS. 16, 17A, and 17B, respectively.

For ease of description, in FIG. 18, an example is provided in which a single column selection line is selected as a count column selection line from a 33rd column selection line group CS33 of the 33rd block BLK33. Also, an example is provided in which a third column selection line CSL3 of the 17th block BLK17, which is a global spare block, corresponds to the third column selection line CSL3 of the 33rd block BLK33.

Referring to FIG. 18, a target column selection line may be selected from among column selection lines CSL1 to CSL64 of a normal region of the 33rd block BLK33. For example, the third column selection line CSL3 of the 33rd block BLK33 may be selected as a target column selection line, and the selected third column selection line CSL3 may be set as a count column selection line.

Then, the third column selection line CSL3 of the 33rd block BLK33 may be mapped to the third column selection line CSL3 of the 17th block BLK17. Accordingly, when there is a request to write normal data in the third column selection line CSL3 of the 33rd block BLK33, memory cells connected to the third column selection line CSL3 of the 17th block BLK17 may store the normal data instead.

As described above, according to an example embodiment, the memory device may select a target column selection line from among the plurality of column selection lines and use the selected target column selection line as a count column selection line. Therefore, even when an RMW operation needs to be performed for a relatively short time, the memory device may reliably perform an RMW operation.

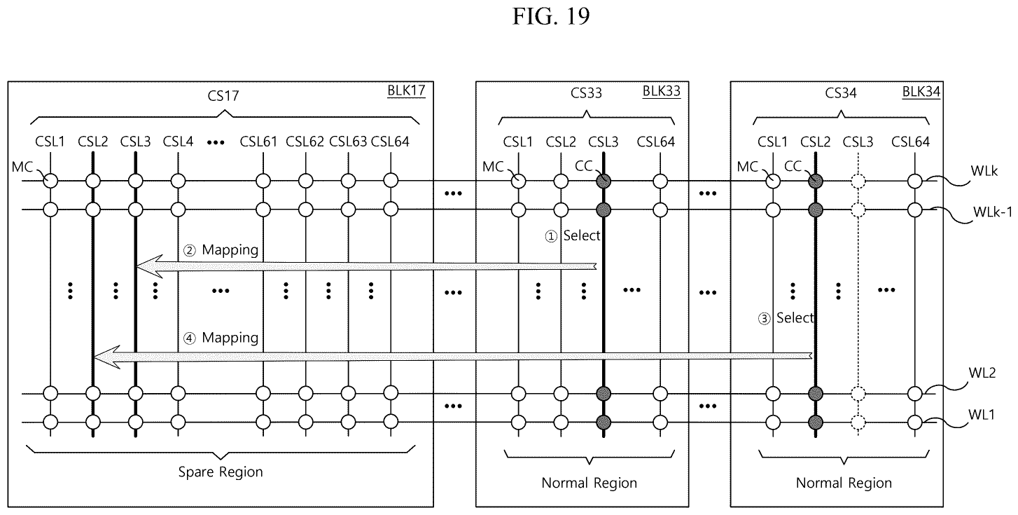

FIG. 19 is a diagram illustrating an example of an operation of setting a count column selection line according to an example embodiment. For ease of description, in FIG. 19, an example is provided in which a single column selection line is selected as a count column selection line from the 33rd column selection line group CS33 and a single column selection line is selected as a count column selection line from a 34th column selection line group CS34 of a 34th block BLK34. In addition, an example is provided in which column selection lines CSL1 to CSL64 of the 33rd block correspond to column selection lines CSL1 to CSL64 of the 17th block BLK17, respectively, and column selection lines CSL1 to CSL64 of the 34th block also correspond to the column selection lines CSL1 to CSL64 of the 17th block BLK17, respectively.

Referring to FIG. 19, a target column selection line may be selected from among the column selection lines CSL1 to CSL64 of the normal region of the 33rd block BLK33. For example, the third column selection line CSL3 of the 33rd block BLK33 may be selected as a target column selection line, and the selected third column selection line CSL3 may be used as a count column selection line.

Then, the third column selection line CSL3 of the 33rd block BLK33 may be mapped to the third column selection line CSL3 of the 17th block BLK17. Accordingly, when there is a request to write normal data in the third column selection line CSL3 of the 33rd block BLK33, memory cells connected to the third column selection line CSL3 of the 17th block BLK17 may store the normal data instead.

In addition, a target column selection line may be selected from among column selection lines CSL1 to CSL64 of a normal region of the 34th block BLK34. The third column selection line CSL3 of the 17th block BLK17 is already storing normal data instead of the third column selection line CSL3 of the 33rd block BLK33, so that the third column selection line CSL3, among the column selection lines CSL1 to CSL64 of the normal region of the 34th block BLK34, may not be selected as a count column selection line. For example, a target column selection line to be used as a count column selection line may be selected from among the column selection lines CSL1, CSL2, CSL4 to CSL64 of the normal region of the 34th block BLK34 except the third column selection line CSL3 of the 34th block BLK34. For example, the second column selection line CSL2 of the 34th block BLK34 may be selected as a target column selection line, and the selected second column selection line CSL2 may be used as a count column selection line.

Then, the second column selection line CSL2 of the 34th block BLK34 may be mapped to the second column selection line CSL2 of the 17th block BLK17. Accordingly, when there is a request to write normal data in the second column selection line CSL2 of the 34th block BLK34, memory cells connected to the second column selection line CSL2 of the 17th block BLK17 may store the normal data instead.

As described above, according to an example embodiment, the memory device may select a target column selection line from among a plurality of column selection lines and use the selected target column selection line as a count column selection line. Therefore, even when an RMW operation needs to be performed for a relatively short time, the memory device may perform an RMW operation. In addition, by checking whether each column selection line of the global spare block GSB is used when the target column selection line is selected, the target column selection line selected as a column selection line may be replaced with the column selection line of the global spare block.

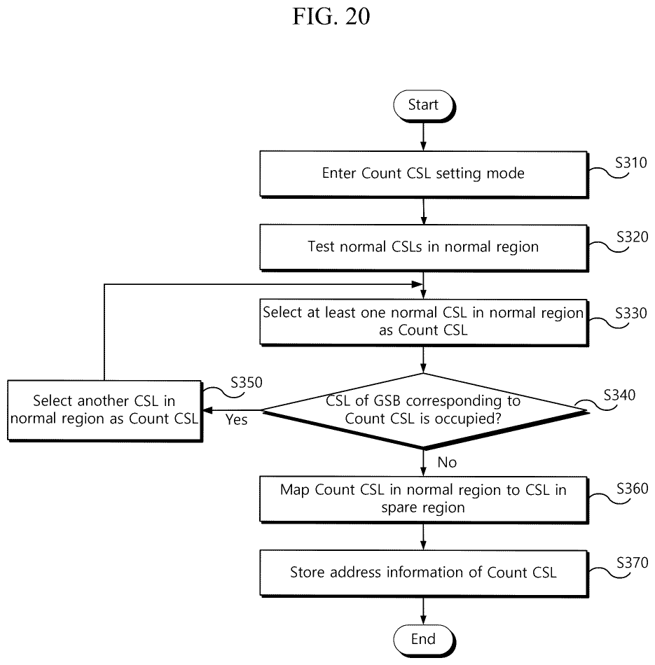

FIG. 20 is a flowchart illustrating an example of an operation of setting a count column selection line in a bank including a global spare block according to an example embodiment. The operation of setting the count column selection line of FIG. 20 is similar to that of FIGS. 13 and 15. Therefore, redundant descriptions will be omitted to avoid repetition.

In operation S310, a memory device may enter a count column selection line setting mode.

In operation S320, the memory device may perform a test operation on a plurality of column selection lines of a normal region.

In operation S330, the memory device may select a target column selection line to be used as a count column selection line from among the plurality of column selection lines of the normal region based on a test result of the test operation performed in operation S320.

In operation S340, the memory device may check whether a column selection line of a global spare block corresponding to the selected target column selection line is already occupied.

If the column selection line of the global spare block corresponding to the selected target column selection line is already occupied, the flow proceeds to operation S350. In operation S350, the memory device may reselect the target column selection line to be used as a count column selection line from among the plurality of column selection lines of the normal region.

If the column selection line of the global spare block corresponding to the selected target column selection line is not yet occupied, the flow proceeds to operation S360.

In operation S360, the memory device may map the count column selection line of the normal region to a corresponding column selection line of the global spare block.

In operation S360, the memory device may store address information of the count column selection line of the normal region.

As described above, even when a bank includes a global spare block, the memory device according to an example embodiment may select a target column selection line from among the plurality of column selection lines of the normal region and use the selected target column selection line as a count column selection line. Therefore, an RMW operation may be performed to prevent row hammer.

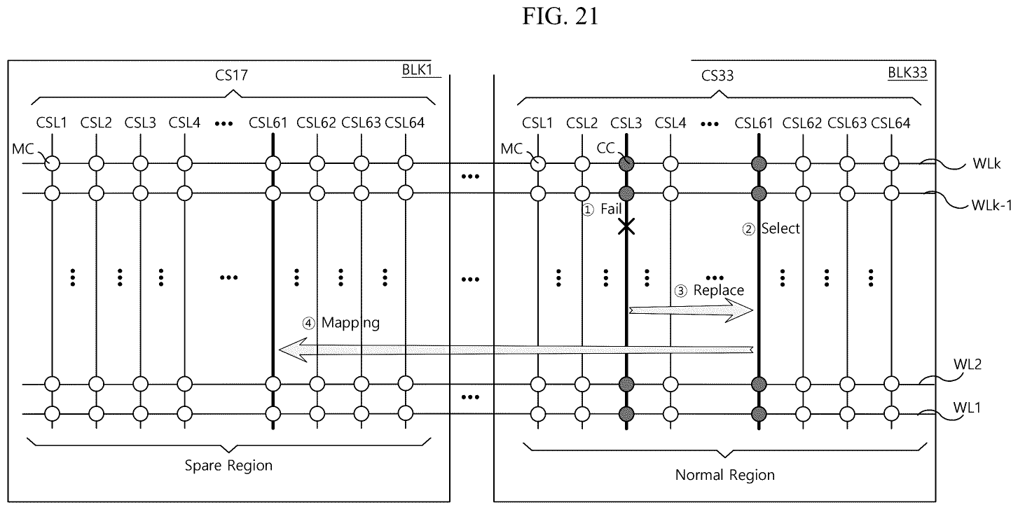

FIG. 21 is a diagram illustrating an example of an operation of setting a count column selection line according to an example embodiment. A 17th block BLK17 and a 33rd block BLK33 of FIG. 21 may correspond to the 17th block BLK17 and the 33rd block BLK33 of FIGS. 16, 17A, and 17B, respectively.

For ease of description, in FIG. 21, an example is provided in which a failure has occurred in the third column selection line CSL3 of the 33rd block BLK33 that is a count column selection line. Also, an example is provided in which a 61st column selection line CSL61 of the 17th block BLK17, which is a global spare block, corresponds to a 61st column selection line CSL61 of the 33rd block BLK33.

Referring to FIG. 21, when a failure occurs in the third column selection line CSL3 of the 33rd block BLK33 that is a count column selection line, a target column selection line may be selected from among column selection lines CSL1, CSL2, CSL4 to CSL64 of the normal region of the 33rd block BLK33. For example, a 61st column selection line CSL61 of the 33rd block BLK33 may be selected as the target column selection line, and the selected 61st column selection line CSL61 may be set as a count column selection line. Accordingly, the count column selection line may continue to be included in the 33rd block BLK33 that is closest to the row hammer management circuit 500.

Then, the 61st column selection line CSL61 of the 33rd block BLK33 may be mapped to the 61st column selection line CSL61 of the 17th block BLK17. Accordingly, when there is a request to write normal data in the 61st column selection line CSL63 of the 33rd block BLK33, memory cells connected to the 61st column selection line CSL61 of the 17th block BLK17 may store the normal data instead.

As described above, according to an example embodiment, even when a failure occurs in a column selection line, a block including the count column selection line may not be changed. As a result, an RMW operation may be performed continuously and reliably to prevent row hammer.

As set forth above, a memory device according to example embodiments may reliably perform an operation to prevent occurrence of row hammer without increasing an additional area.

While example embodiments have been shown and described above, it will be apparent to those skilled in the art that modifications and variations could be made without departing from the scope of the present inventive concept as defined by the appended claims.

What is claimed is:

1. A memory device comprising:
a bank comprising a plurality of memory cells connected to a plurality of wordlines and a plurality of column selection lines;
a row hammer management circuit configured to:
perform a read-modify-write (RMW) operation on count memory cells to read count data corresponding to an activated wordline among the plurality of wordlines, wherein the plurality of memory cells include the count memory cells configured to store the count data a number of access to the activated wordline,
update the read count data, and
write the updated count data in the count memory cells; and
a control logic configured to select a first count column selection line connected to the count memory cells from among the plurality of column selection lines based on writing characteristics of each of the plurality of column selection lines.

2. The memory device of claim 1,
wherein the control logic is configured to map first address information of the first count column selection line to second address information of a second column selection line, other than the first count column selection line, among the plurality of column selection lines.

3. The memory device of claim 2,
wherein the control logic is configured to store the first address information of the first count column selection line.

4. The memory device of claim 3,
wherein the control logic is configured to store the second address information of the second column selection line mapped to the first address information of the first count column selection line.

5. The memory device of claim 1,
wherein the bank comprises:
a first block comprising a first normal region and a first spare region; and
a second block comprising a second normal region and a second spare region, and
wherein the control logic is configured to:
select a target column selection line from among a plurality of column selection lines disposed in the first normal region, and
set the target column selection line as the first count column selection line connected to the count memory cells.

6. The memory device of claim 5,
wherein the first block is disposed to be closer to the row hammer management circuit compared to the second block.

7. The memory device of claim 5,
wherein the control logic is configured to map address information of the target column selection line of the first normal region to address information of a column selection line among a plurality of column select lines disposed in the first spare region.

8. The memory device of claim 7,
wherein the control logic is configured to:
select the column selection line among the plurality of column selection lines in the first spare region to be mapped to the target column selection line of the first normal region, and
store mapping information between the address information of the target column selection line of the first normal region and the address information of the column selection line of the first spare region.

9. The memory device of claim 1,
wherein the bank comprises:
a first block comprising a first normal region; and
a second block comprising a spare region, and
wherein the control logic is configured to:
selects a target column selection line from among a plurality of column selection lines disposed in the first normal region of the first block, and
set the target column selection line of the first normal region of the first block as the first count column selection line connected to the count memory cells.

10. The memory device of claim 9,
wherein the first block is disposed to be closer to the row hammer management circuit compared to the second block.

11. The memory device of claim 9,
wherein the control logic is configured to map the target column selection line of the first normal region of the first block to a column selection line among a plurality of column selection lines of the spare region of the second block.

12. The memory device of claim 9,
wherein the bank further comprises a third block comprising a second normal region,
wherein the control logic is configured to select a target column selection line from among a plurality of column selection lines disposed in the second normal region of the third block, based on address information of the first count column selection line of the first normal region of the first block, and
wherein the address information of the first count column selection line in the first block is different from address information of the target column selection line of the third block.

13. The memory device of claim 9,
wherein when the first count column selection line selected from the first normal region of the first block fails, the control logic is configured to:
select, in response to fail of the first count column selection line of the first block, a second target column selection line from among the plurality of column selection lines disposed in the first normal region of the first block, and
set the second target column selection line as a count column selection line of the first block.

14. The memory device of claim 13,
wherein the control logic is configured to map address information of the count column selection line of the first normal region of the first block to address information of one of a plurality of column selection lines of the spare region of the second block.

15. A method of operating a memory device comprising:
selecting a first column selection line from among a plurality of column selection lines as a first count column selection line connected to count memory cells storing count data representing a number of access to each of a plurality of wordlines, based on writing characteristics of each of the plurality of column selection lines; and
mapping address information of the first count column selection line to address information of a second column selection line among the plurality of column selection lines.

16. The method of claim 15, further comprising:
storing mapping information of the mapping of the address information of the first count column selection line to the address information of the second column selection line.

17. The method of claim 15,
wherein the first column selection line is selected from a first block, and
wherein the second column selection line is selected from a second block.

18. The method of claim 17, further comprising:
selecting a third column selection line to be used as a second count column selection line from among a plurality of column selection lines of a third block, based on writing characteristics of each of the plurality of column selection lines of the third block and address information of the first column selection line of the first block.

19. The method of claim 15, further comprising:
selecting, in response to fail of the first column selection line, a third column selection line to be used as a second count column selection line of the first block among a plurality of column selection lines of the first block, based on writing characteristics of each of the plurality of column selection lines of the first block.

20. A memory system comprising:
a memory device configured to store data; and
a memory controller configured to control the memory device,
wherein the memory device comprises:
a bank comprising a plurality of memory cells connected to a plurality of wordlines and a plurality of column selection lines;
a row hammer management circuit configured to:
perform a read-modify-write (RMW) operation on count memory cells to read count data corresponding to an activated wordline among the plurality of wordlines, wherein the plurality of memory cells include the count memory cells configured to store the count data representing a number of access to the activated wordline,
update the read count data, and
write the updated count data in the bank; and
a control logic configured to select at least one count column selection line connected to the count memory cells from among the plurality of column selection lines based on writing characteristics of each of the plurality of column selection lines.
